(19) United States
(12) Patent Application Publication
(10) Pub. No.: US 2024/0006161 A1
(43) Pub. Date: Jan. 4, 2024

(54) SUBSTRATE PROCESSING METHOD AND SUBSTRATE PROCESSING DEVICE

(71) Applicant: ASM IP Holding B.V., Almere (NL)

(72) Inventors: HaeIn Kim, Hwaseong-si (KR); HakJoo Lee, Hwaseong-si (KR); KiKang Kim, Yongin-si (KR); YongWoong Jeong, Hwaseong-si (KR); YoungMin Kim, Hwaseong-si (KR)

(21) Appl. No.: 18/214,255

(22) Filed: Jun. 26, 2023

Related U.S. Application Data
(60) Provisional application No. 63/356,727, filed on Jun. 29, 2022.

(51) Int. Cl. H01J 37/32

(52) U.S. Cl. CPC H01J 37/32449; H01J 37/32266; H01J 37/32853; H01J 2237/334; H01J 2237/327

(57) ABSTRACT

A substrate processing method capable of preventing a damage to a reactor and a lower film includes: supplying a substrate having a pattern structure; forming a layer on the pattern structure; generating active species by applying plasma on the substrate; and selectively etching a layer on the pattern structure generated by the active species by performing isotropic etching on the layer, wherein the applying of the plasma includes: increasing a density of the active species; and increasing a mobility of the active species.

### CROSS-REFERENCE TO RELATED APPLICATIONS

This application claims priority to U.S. Provisional Patent Application Ser. No. 63/356,727 filed Jun. 29, 2022 and titled SUBSTRATE PROCESSING METHOD, the disclosure of which is hereby incorporated by reference in its entirety.

### BACKGROUND

### 1. Field

One or more embodiments relate to a substrate processing method, and more particularly, to a substrate processing method for selectively forming a film on the top or side of a pattern structure included in a substrate.

### 2. Description of the Related Art

As a circuit line width of a semiconductor device is decreased, the shape of a structure constituting the semiconductor device is also changing. For example, in the case of 3D VNAND, multiple gate structures are configured in a vertical form to overcome the limitations of integration. In the case of a vertical structure, in order to stack a plurality of insulating layers and connect electrode layers on the top or side of one end of each insulating layer, a technique for selectively depositing a layer on the corresponding surface is required.

U.S. Pat. No. 10,134,757 discloses a method of selectively forming a SiN film on the exposed top of a step-shaped pattern structure using a plasma atomic layer method. In more detail, a method of removing a SiN film on the side of a stepped structure while keeping a SiN film on the top of the stepped structure by differentiating etching characteristics of the SiN films on the top and side of the step by applying RF power to form the SiN film is disclosed. For example, due to an ion bombardment effect when RF power is applied, the SiN film formed on the top of the stepped structure may be made denser, and the etch resistance may be improved compared to that of the SiN film on the side.

Alternatively, by further increasing the applied RF power, the SiN film formed on the top of the stepped structure may be destroyed, and the etch resistance may be less than that of the SiN film on the side of the stepped structure by lowering the hardness of the SiN film. In addition, after wet etching is performed, the SiN film formed on the top may be removed and the SiN film formed on the side may remain thereon. However, when increasing the applied RF power, a lower film may be damaged by radicals and active ionic species, and a reactor for performing substrate processing may also be damaged.

### SUMMARY

One or more embodiments include a method for preventing such damage problems. In more detail, one or more embodiments include a substrate processing method that allows a thin film to be removed and remained by location by controlling etch rate of the thin film without excessively increasing RF power applied in a process of selectively removing the thin film on a pattern structure through isotropic etching.

Additional aspects will be set forth in part in the description which follows and, in part, will be apparent from the description, or may be learned by practice of the presented embodiments of the disclosure.

According to one or more embodiments, a substrate processing method includes: supplying a substrate having a pattern structure; forming a layer on the pattern structure; generating active species by applying plasma; and selectively etching a layer on a pattern structure generated by the active species by performing isotropic etching on the layer, wherein the applying of the plasma may include: increasing density of the active species; and increasing mobility of the active species.

According to an example of the substrate processing method, the substrate processing method may further include supplying a first gas; and supplying a second gas, wherein a cycle including the supplying of the first gas, the supplying of the second gas, and generating active species by applying the plasma is performed a plurality of times, and the isotropic etching may be performed after the cycle.

According to another example of the substrate processing method, the increase of the density of the active species is performed by applying first plasma, and the increase of the mobility of the active species may be performed by applying second plasma different from the first plasma.

According to another example of the substrate processing method, a frequency of the first plasma may be greater than a frequency of the second plasma.

According to another example of the substrate processing method, a location of a portion where the layer is etched by the isotropic etching may depend on a first ratio of a second power level of the second plasma to a first power level of the first plasma.

According to another example of the substrate processing method, the first power intensity may be in a range of 50 W to 300 W, and more preferably, the first power intensity may be in a range of 100 W to 200 W.

According to another example of the substrate processing method, the second power intensity may be in a range of 60 W to 150 W.

According to another example of the substrate processing method, the first ratio may exceed a certain value, and the layer may remain on a side of the pattern structure.

According to another example of the substrate processing method, the pattern structure may include top, bottom, and the side connecting the top and the bottom, and the layer may include a first layer on the top, a second layer on the bottom, and a third layer on the side, wherein during the isotropic etching, the first layer may be etched at a first etch rate, the second layer may be etched at a second etch rate, and the third layer may be etched at a third etch rate.

According to another example of the substrate processing method, the third etch rate may be less than the first etch rate and less than the second etch rate.

According to another example of the substrate processing method, a second ratio of the first etch rate to the second etch rate may be proportional to an increase in the first ratio.

According to another example of the substrate processing method, the substrate processing method may be performed using a substrate processing device, and the substrate processing device may include a power generator configured to apply the plasma.

According to another example of the substrate processing method, the substrate processing device may further include a matching network between the power generator and a reactor.

According to another example of the substrate processing method, the power generator may include: a first power generator configured to generate first plasma at a first frequency; and a second power generator configured to generate second plasma at a second frequency less than the first frequency.

According to another example of the substrate processing method, the matching network may be configured to perform impedance matching between the first and second power generators and the reactor.

According to one or more embodiments, a substrate processing method includes: supplying a substrate having a pattern structure; forming a layer by applying a first plasma having a first frequency and a second plasma having a second frequency less than the first frequency on the pattern structure; and performing selective etching on the layer by isotropically etching the layer, wherein a location of a portion where the layer remains by the selective etching may depend on a ratio of a second power level of the second plasma to a first power level of the first plasma.

According to an example of the substrate processing method, a cycle may be repeated a plurality of times during the forming of the layer, and the cycle may include: supplying a first gas; purging the first gas; supplying a second gas; applying the first plasma; applying the second plasma; and purging the second gas.

According to one or more embodiments, a substrate processing device includes: a substrate support configured to support a substrate; a gas inlet on the substrate support; a first power generator connected to the gas inlet; and a second power generator connected to the gas inlet, wherein a first frequency of first plasma generated by the first power generator may be greater than a second frequency of second plasma generated by the second power generator.

According to an example of the substrate processing device, the substrate processing device may further include a matching network between the gas inlet and the first and second power generators.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart of a substrate processing method according to embodiments;

FIGS. 2 to 5 are flowcharts of substrate processing methods according to embodiments of the inventive concept;

FIG. 6 is a flowchart schematically illustrating a substrate processing method according to embodiments of the inventive concept;

FIG. 7 is a conceptual diagram of a film formed according to a substrate processing method in which films formed on the top and bottom of a pattern structure are removed and a film on the side of the pattern structure remains;

FIG. 8 is a view illustrating an etch rate (WER; Wet Etch Rate) of a film according to the level of RF power applied;

FIG. 9 is a flowchart illustrating a substrate processing method according to an embodiment;

FIG. 10 is a timing diagram for a deposition step of FIG. 9;

FIG. 11 is a graph illustrating a Wet Etch Rate (WER) of SiN films on the top, side, and bottom after deposition and wet etching according to the substrate processing method of FIGS. 9 and 10;

FIG. 12 is a graph illustrating wet etch selectivity for comparing WERs of SiN films for each location of a gap structure in FIG. 11;

FIG. 13 is a view illustrating whether low-frequency RF power is applied and whether films on the top and bottom are etched according to the level of the applied power;

FIG. 14 is a conceptual diagram illustrating an etch rate of a film on a bottom and a side wall according to the intensity of applied low-frequency RF power; and

FIG. 15 is a schematic view of a structure of a reactor for performing film deposition according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, one or more embodiments will be described more fully with reference to the accompanying drawings.

In this regard, the embodiments may have different forms and should not be construed as being limited to the descriptions set forth herein. Rather, these embodiments are provided so that the disclosure will be thorough and complete, and will fully convey the scope of the disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

In the disclosure, “gas” may include evaporated solids and/or liquids and may include a single gas or a mixture of gases. In the disclosure, a process gas introduced into a reaction chamber through a shower head may include a precursor gas and an additive gas. The precursor gas and the additive gas may typically be introduced as a mixed gas or may be separately introduced into a reaction space. The precursor gas may be introduced together with a carrier gas such as an inert gas. The additive gas may include a dilution gas such as a reactive gas and an inert gas. The reactive gas and the dilution gas may be mixedly or separately introduced into the reaction space. The precursor may include two or more precursors, and the reactive gas may include two or more reactive gases. The precursor may be a gas that is chemisorbed onto a substrate and typically contains metalloid or metal elements constituting a main structure of a matrix of a dielectric film, and the reactive gas for deposition may be a gas that is reactive with the precursor chemisorbed onto the substrate when excited to fix an atomic layer or a monolayer on the substrate. The term “chemisorption” may refer to chemical saturation adsorption. A gas other than the process gas, that is, a gas introduced without passing through the shower head, may be used to seal the reaction space, and it may include a seal gas such as an inert gas. In some embodiments, the term “film” may refer to a layer that extends continuously in a direction perpendicular to a thickness direction without substantially having pinholes to cover an entire target or a relevant surface, or may refer to a layer that simply covers a target or a relevant surface. In some embodiments, the term “layer” may refer to a structure, or a synonym of a film, or a non-film structure having any thickness formed on a surface. The film or layer may include a discrete single film or layer or multiple films or layers having some characteristics, and the boundary between adjacent films or layers may be clear or unclear and may be set based on physical, chemical, and/or some other characteristics, formation processes or sequences, and/or functions or purposes of the adjacent films or layers.

In the disclosure, the expression “containing an Si—N bond” may be referred to as characterized by an Si—N bond or Si—N bonds having a main skeleton substantially constituted by the Si—N bond or Si—N bonds and/or having a substituent substantially constituted by the Si—N bond or Si—N bonds. A silicon nitride layer may be a dielectric layer containing a Si—N bond, and may include a silicon nitride layer (SiN) and a silicon oxynitride layer (SiON).

In the disclosure, the expression “same material” should be interpreted as meaning that main components (constituents) are the same. For example, when a first layer and a second layer are both silicon nitride layers and are formed of the same material, the first layer may be selected from the group consisting of Si₂N, SiN, Si₃N₄, and Si₂N₃ and the second layer may also be selected from the above group but a particular film quality thereof may be different from that of the first layer.

Additionally, in the disclosure, according as an operable range may be determined based on a regular job, any two variables may constitute an operable range of the variable and any indicated range may include or exclude terminated sites. Additionally, the values of any indicated variables may refer to exact values or approximate values (regardless of whether they are indicated as “about”), may include equivalents, and may refer to an average value, a median value, a representative value, a majority value, or the like.

In the disclosure where conditions and/or structures are not specified, those of ordinary skill in the art may easily provide these conditions and/or structures as a matter of customary experiment in the light of the disclosure. In all described embodiments, any component used in an embodiment may be replaced with any equivalent component thereof, including those explicitly, necessarily, or essentially described herein, for intended purposes, and in addition, the disclosure may be similarly applied to devices and methods.

Hereinafter, embodiments of the disclosure will be described with reference to the accompanying drawings. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

Embodiments will be described hereinafter with reference to the drawings in which embodiments are schematically illustrated. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

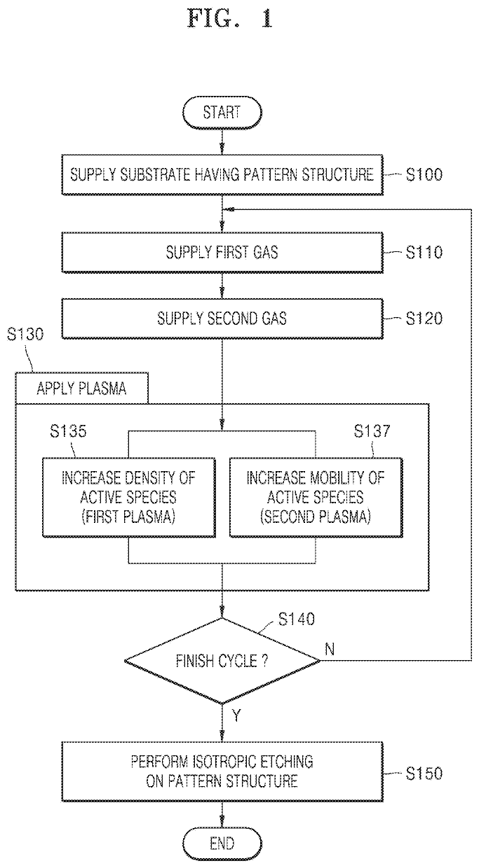

FIG. 1 is a flowchart of a substrate processing method according to embodiments.

Referring to FIG. 1, the substrate processing method may include a substrate supply step (S100), a first gas supply step (S110), a second gas supply step (S120), a plasma application step (S130), and an isotropic etching step (S150).

During the substrate supply step (S100), a substrate having a pattern structure may be supplied into a reactor of a substrate processing device. The substrate may be, for example, a semiconductor substrate or a display substrate. The substrate may include, for example, any one of silicon, silicon-on-insulator, silicon-on-sapphire, germanium, silicon-germanium, and gallium-arsenide.

The pattern structure included in the substrate may have the top, bottom, and side connecting the top and the bottom. Such a pattern structure may be a structure having a high aspect ratio, and the aspect ratio may be, for example, width:length=1:10 or more. In some embodiments, the pattern structure may include a gap, that is, a recess, having an aspect ratio. In some other embodiments, the pattern structure may be a stepped structure. In some additional embodiments, a metal wire may be formed on the stepped structure.

Thereafter, the first gas supply step (S110) and the second gas supply step (S120) are performed. A first gas and a second gas may be sequentially supplied as shown in FIG. 1, and in another example, the first gas and the second gas may be supplied simultaneously. In another embodiment, the first gas and the second gas may be supplied in an order opposite to that shown in FIG. 1. That is, the first gas may be supplied after the second gas is supplied first.

In some embodiments, the first gas may include a material that is chemisorbed on the substrate as a source gas. The second gas is a reactant and may include a material reactive with the first gas, in particular a material reactive with the first gas under a plasma atmosphere. Although not shown in the drawings, in some embodiments, a purge step may be performed between the first gas supply step and the second gas supply step.

The first gas may include a precursor for layer formation. For example, when a silicon oxide layer and/or a silicon nitride layer are to be formed on the pattern structure, the first gas may include a silicon precursor. The second gas may be selected to react with the precursor to form a desired layer. For example, when a silicon oxide layer is to be formed, the second gas may include an oxygen-containing material. In another example, when a silicon nitride layer is to be formed, the second gas may include a nitrogen-containing material.

After the supply of the first gas and the second gas, the plasma application step (S130) is performed. During the plasma application step (S130), the second gas may be excited to generate active species, the active species of the second gas having reactivity may react with the first gas to form a layer on the pattern structure. In some embodiments, the second gas supply step (S120) and the plasma application step (S130) may be performed simultaneously. In another example, the second gas supply step (S120) may be performed first, and the plasma application step (S130) may be performed while the second gas supply step (S120) is continued.

The layer formed during the plasma application step (S130) may have different etch resistance for each location. For example, plasma having directionality is applied on a pattern structure having the top, bottom, and side, so that a layer having high etch resistance may be formed on the top and bottom of the pattern structure, and a layer having low etch resistance may be formed on the side of the pattern structure. On the contrary, a layer having low etch resistance may be formed on the top and bottom of the pattern structure, and a layer having high etch resistance may be formed on the side of the pattern structure. Thus, the layer may be selectively removed during a subsequent isotropic etching process.

The plasma application step (S130) may include a step of increasing the density of active species (S135) and a step of increasing the mobility of active species (S137). In some embodiments, the step of increasing the density of active species (S135) and the step of increasing the mobility of active species (S137) may be performed by applying plasmas of different frequencies. For example, the step of increasing the density of active species (S135) may be implemented through a step of applying first plasma of a high frequency (e.g., 13.35 MHz). In addition, the step of increasing the mobility of active species (S137) may be implemented through a step of applying second plasma of a low frequency (e.g., 430 kHz).

The step of increasing the density of active species (S135) and the step of increasing the mobility of active species (S137) may be implemented by adjusting other process parameters other than a plasma frequency. For example, by applying the first plasma and the second plasma having different duty ratios, the step of increasing the density of active species (S135) and the step of increasing the mobility of active species (S137) may be performed. In another embodiment, the first plasma and the second plasma may be applied under different pressures.

The first gas supply step (S110), the second gas supply step (S120), and the plasma application step (S130) may be repeatedly performed as one cycle, and after determining that the cycle is finished (S140), an isotropic etching step (S150) may be performed. The isotropic etching step (S150) may be implemented by, for example, a wet etching method such as immersion. As a specific example, a diluted hydrofluoric acid (dHF) solution diluted 1:100 during the isotropic etching may be used.

As described above, because a layer formed on the pattern structure has different etch resistance depending on the location, the layer may be removed or remain during the isotropic etching depending on the location. For example, after the isotropic etching of the pattern structure, a layer may remain on the top and bottom of the pattern structure. In another example, after the isotropic etching of the pattern structure, a layer may remain on the side of the pattern structure.

In some embodiments, when the step of increasing the density of active species (S135) and the step of increasing the mobility of the active species (S137) are performed by applying the first plasma and the second plasma, respectively, a location of a portion where the layer is etched by the isotropic etching may depend on a first ratio of a second power level of the second plasma to the first power level of the first plasma.

Since the plasma having the directionality is applied during the plasma application step (S130), as the second power level of the second plasma applied during the step of increasing the mobility of active species (S137) increases compared to the first power level of the first plasma applied during the step of increasing the density of active species (S135), movement of the plasma having the directionality may increase. As a result, a change in the etch resistance according to the location of the layer on the pattern structure may become more clear.

For example, when plasma is applied in a direction toward the top and bottom of the pattern structure, as the level of the second power increases, the layers on the top and bottom of the pattern structure may be more affected by plasma. In this case, the etch resistance of the layers on the top and bottom of the pattern structure may be reduced by the first plasma supplied during the step of increasing the density of active species (S135) and the second plasma supplied during the step of increasing the mobility of active species (S137), Thereafter, during the isotropic etching, the layers on the top and bottom of the pattern structure may be partially removed, and the layer on the side of the pattern structure may remain.

This trend is more specifically illustrated in FIG. 11. Referring to FIG. 11, when a first power intensity of high-frequency first plasma for increasing the density of active species of plasma is 115 W and when a second power intensity of low-frequency second plasma for increasing the mobility of active species of plasma is 30 W, it can be seen that an isotropic etch rate of layers on top and bottom of a pattern structure is not significantly different from an isotropic etch rate of a layer on the side of the pattern structure. On the other hand, when the second power intensity of the second plasma compared to the first power intensity of the first plasma increases to 80 W or 130 W, it can be seen that the isotropic etch rate of the layers on the top and bottom of the pattern structure increases by about 15 times the isotropic etch rate of the layer on the side of the pattern structure. Accordingly, the layers on the top and bottom of the pattern structure may be selectively removed during isotropic etching.

When a first ratio of the second power level to the first power level exceeds a certain value, the layer may remain on the side of the pattern structure. For example, in the example of FIG. 11 where the first power level is 115 W, when the second power intensity exceeds 57.5 W (i.e., when the first ratio exceeds 0.5), desired etch selectivity may be achieved during isotropic etching. In more detail, when a layer of the pattern structure includes a first layer on the top surface, a second layer on the bottom surface, and a third layer on the side, during the isotropic etching, the first layer may be etched at a first etch rate, the second layer may be etched at a second etch rate, and the third layer may be etched at a third etch rate less than the first etch rate and the second etch rate.

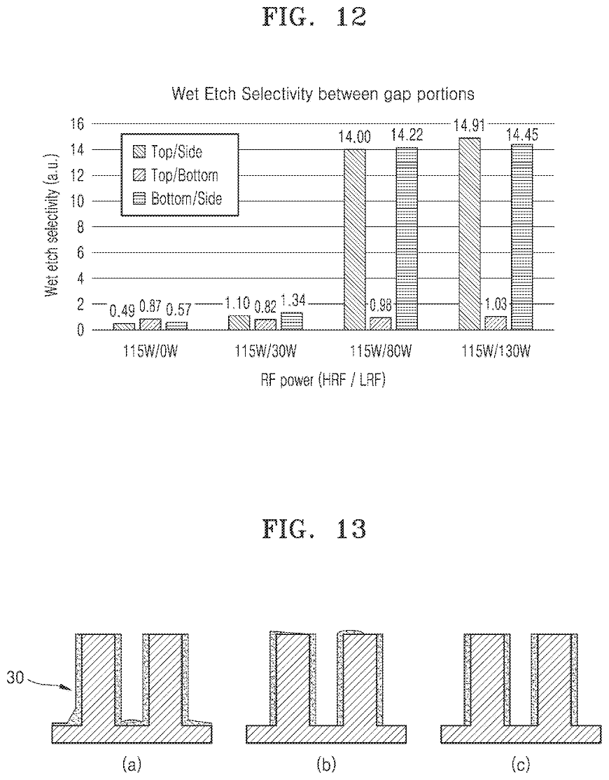

In some embodiments, a second ratio of the first etch rate on the top to the second etch rate on the bottom may be proportional to an increase in the first ratio. This trend may be derived from an experimental example of FIG. 12. Referring to FIG. 12, it can be seen that when a first ratio of the intensity of second power of second plasma to the intensity of first power of first plasma is 0.26 (i.e. 115 W/30 W), a second ratio (wet etch selectivity of top/bottom) is 0.82, whereas when the first ratio is 0.7 (115 W/80 W), the second ratio increases to 0.98, and when the second ratio is 1.13 (115 W/130 W), the second ratio increases to 1.03.

It should be noted that although the above examples have been illustrated and described on the assumption that the first power intensity is 115 W, the disclosure is not limited thereto. The first power intensity may be in the range of 50 W to 300 W, and in a preferred embodiment, the first power intensity may be in the range of 100 W to 200 W. In addition, the second power intensity may be in the range of 20 W to 200 W, and in a preferred embodiment, the second power intensity may be in the range of 30 W to 150 W.

In the process of selectively removing a layer on a pattern structure through isotropic etching, because directional plasma is applied to the top and bottom of the pattern structure, densification of layers on the top and bottom by plasma application (and selective removal of a layer on the side of the pattern structure by subsequent isotropic etching) may be achieved without increasing plasma power. However, in the case of the prior art, in order to weaken the layers on the top and bottom by plasma application (and selective removal of the layers on the top and bottom by subsequent isotropic etching), plasma power great enough to achieve the weakening (e.g., 800 W or more) needs to be applied, so damage to the pattern structure under the layers or damage to a reactor may occur.

According to embodiments of the inventive concept, a technical effect of selectively removing the layers on the top and bottom of the pattern structure without increasing the power intensity of the directional plasma may be achieved. As described above, the first power intensity may be in the range of 50 W to 300 W, and the second power intensity may be in the range of 20 W to 200 W. Since this power range is reduced compared to the power intensity required in the prior art (i.e., more than 800 W), damage to the pattern structure under the layers or damage to a reactor may be prevented.

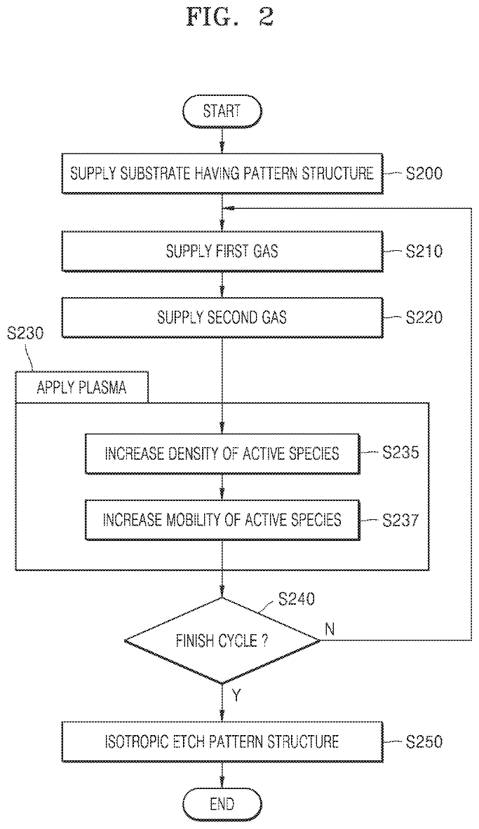

FIGS. 2 to 5 are flowcharts of substrate processing methods according to embodiments of the inventive concept. The substrate processing methods according to the embodiments may be modified examples of the substrate processing methods according to the above-described embodiments.

For example, the substrate processing methods shown in FIGS. 2 to 5 may include substrate supply steps (S200, S300, S400, and S500), first gas supply steps (S210, S310, S410, and S510), second gas supply steps (S220, S320, S420, and S520), plasma application steps (S230, S330, S430, and S530), and isotropic etching steps (S250, S350, S450, and S550), and these steps may correspond to the steps described in FIG. 1. Hereinafter, repeated descriptions of the embodiments will not be given herein.

In some embodiments, the step of increasing the mobility of active species and the step of increasing the density of active species, which are performed during the plasma application step, may be sequentially performed. For example, as shown in FIG. 2, the step of increasing the density of active species (S235) may be performed first, and then the step of increasing the mobility of active species (S237) may be performed.

Although not shown in FIG. 2, in some embodiments, a purge step may be performed between the step of increasing the mobility of the active species (S235) and the step of increasing the density of active species (S237). For example, when plasma is used to increase the mobility and density of active species, the purge step may be performed between plasma application steps. During the purge step, the second gas may be continuously supplied.

In some additional examples, a first plasma may be applied to increase the density of active species, and a second plasma may be applied to increase the mobility of the active species. In this case, the first plasma application step and the second plasma application step may be sequentially performed. In another example, as shown in FIG. 1, the first plasma application step and the second plasma application step may be performed simultaneously.

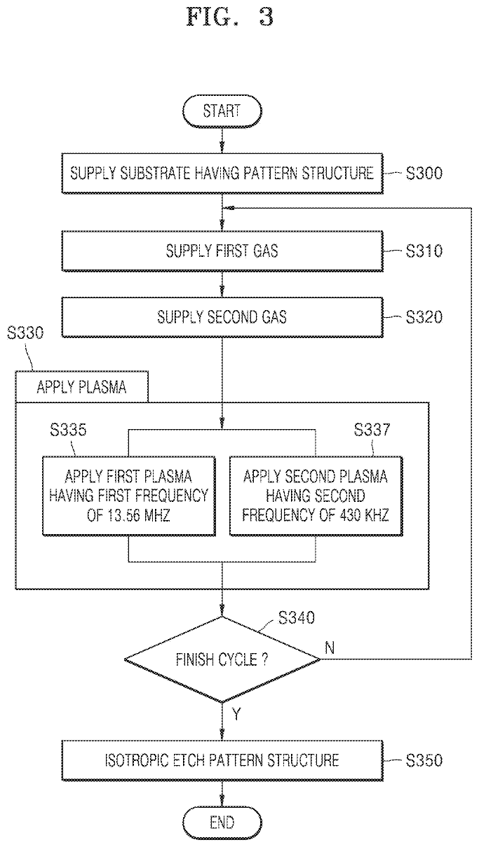

FIG. 3 illustrates a state in which a first plasma application step (S335) and a second plasma application step (S337) are simultaneously performed. As a specific example, a first plasma having a first frequency of 13.56 MHz and a second plasma having a second frequency of 430 kHz may be supplied to a reactor. By supplying the first plasma of 13.56 MHz which is a high frequency and the second plasma of 430 kHz which is a low frequency simultaneously or sequentially, active species in the reactor may be introduced into a bottom of a pattern structure more efficiently.

It should be noted that the above-described numerical values (i.e., 13.56 MHz and 430 kHz) as examples of high and low frequencies are exemplary and the inventive concept is not limited thereto. The first frequency as a high frequency may be a frequency suitable for increasing the density of active species, and the second frequency as a low frequency may be a frequency suitable for increasing the mobility of active species. Selection of these frequencies may be altered based on the dimensions of a pattern structure and other process parameters.

As an optional embodiment, in the plasma application step (S330) shown in FIG. 3, the first plasma application step (S335) may be omitted. In other words, during the plasma application step, only the second plasma having the second frequency may be supplied to the reactor. The inventors have discovered that even when a layer is formed on a pattern structure using only low-frequency plasma (e.g., 430 kHz), the etch resistance of the layer may be changed for each location. The change in the etch resistance for each location may depend on a power level of the low-frequency plasma.

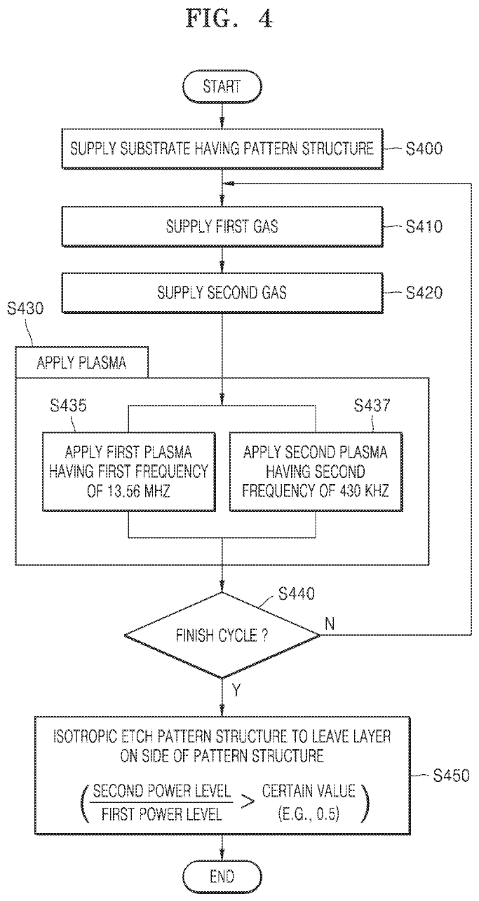

FIG. 4 illustrates an example in which a layer formed on a pattern structure remains on the side of the pattern structure after isotropic etching. As described above in the embodiment of FIG. 1, a location of a portion where a layer is etched during the isotropic etching step (S450) may depend on a ratio of power levels of first plasma to second plasma.

For example, a plasma of a first frequency may be set to be applied at a first power level during the first plasma application step (S435) and a plasma of a second frequency may be set to be applied at a second power level during the second plasma application step (S437) so that more layers on the top and bottom of the pattern structure are etched so that a layer on the side of the pattern structure remains. In addition, a ratio of a second power level to a first power level (hereinafter referred to as a ‘power level ratio’) may be set to exceed a certain value (e.g., 0.5).

By performing the plasma application step (S430) based on these settings, the etch resistance of the layer on the pattern structure may be partially changed. In more detail, by setting a power level ratio to exceed 0.5, the etch resistance of the layers on the top and bottom of the pattern structure may be reduced. Accordingly, by subsequent isotropic etching, the layers on the top and bottom of which the etch resistance is reduced may be removed, and the layers on the side of the pattern structure may remain.

These results are shown in more detail in FIG. 11. As shown in FIG. 11, when the power level ratio is 0, more portions of the layer on the side of the pattern structure may be etched (see 115 W/0 W in FIG. 11), when the power level ratio is 0.26, the layer on the pattern structure may be etched uniformly (see 115 W/30 W in FIG. 11), and when the power level ratio is 0.7 or more, more portions of the layers on the top and bottom of the pattern structure may be etched (see 115 W/80 W and 115 W/130 W in FIG. 11). In other words, as the second power level applied increases, an etch rate at the side decreases (the etch resistance increases).

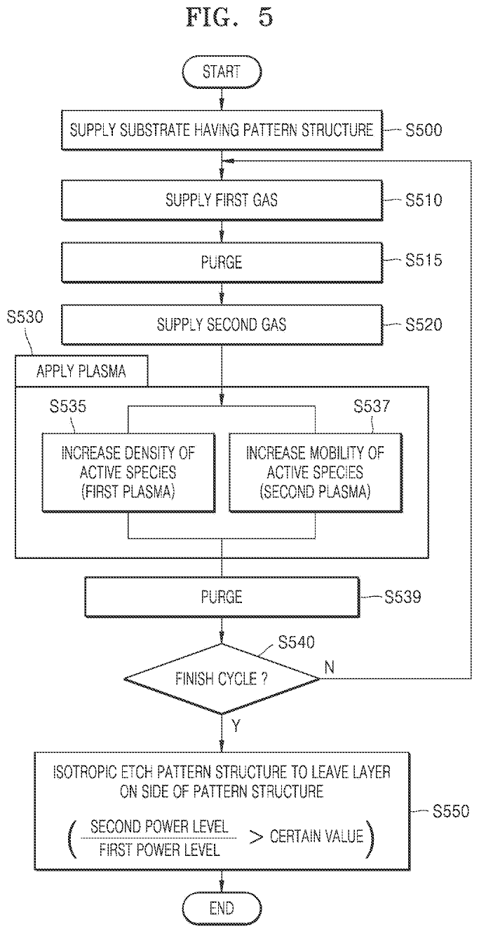

FIG. 5 shows an example in which a layer formed on a pattern structure remains on the side of the pattern structure after isotropic etching, the example in which first plasma is applied during the step of increasing the density of active species (S535) and second plasma is applied during the step of increasing the mobility of active species (S537), but a layer remains on the side of a pattern structure after isotropic etching by making a ratio of a power level of second plasma to a power level of first plasma to be greater than or equal to a certain value.

Referring to FIG. 5, as an additional and optional example, a first gas purge step (S515) may be performed between a first gas supply step (S510) and a plasma application step (S530). In addition, after the plasma application step (S530), a second gas purge step (S539) may be performed. These purge steps (S515 and S539) may be used when, for example, a layer is formed on the pattern structure using an atomic layer deposition process.

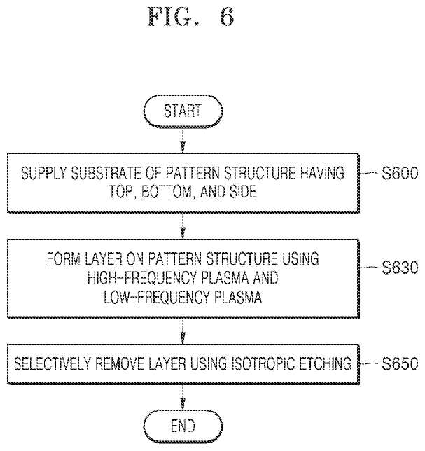

FIG. 6 is a flowchart schematically illustrating a substrate processing method according to embodiments of the inventive concept. The substrate processing methods according to the embodiments may be modified examples of the substrate processing methods according to the above-described embodiments.

Referring to FIG. 6, the substrate processing method is used for processing a substrate of a pattern structure having top, bottom, and side connecting the top and the bottom, the method allows selective removal of a layer from a pattern structure by isotropic etching of a substrate.

To this end, a substrate is first supplied (S600), a layer is formed on a pattern structure (S630), and then isotropic etching is performed on the layer (S650). However, because the isotropic etching generally removes a layer uniformly due to its characteristics, for selective removal, it is necessary to adjust etch resistance of the layer in advance for each location when forming the layer.

The disclosure uses high-frequency plasma and low-frequency plasma to adjust the etch resistance for each location. In other words, by forming a layer using the two types of plasmas described above, etch resistance of the formed layer is changed for each location. It should be noted that the application of plasma having two types of frequencies (S630), a high frequency and a low frequency, is a configuration introduced in connection with the subsequent isotropic etching step (S650).

For example, although a process of applying plasma having two kinds of frequencies, a high frequency and a low frequency, may be mentioned in the prior art, these two types of frequencies mentioned in the prior art are distinguished from the present disclosure unless they are associated with a subsequent isotropic etching process. That is, because the configuration of the two types of frequencies of the disclosure is related to the subsequent isotropic etching process, even if there is a prior art using plasma having two types of frequencies for different purposes, both need to be regarded as different inventions.

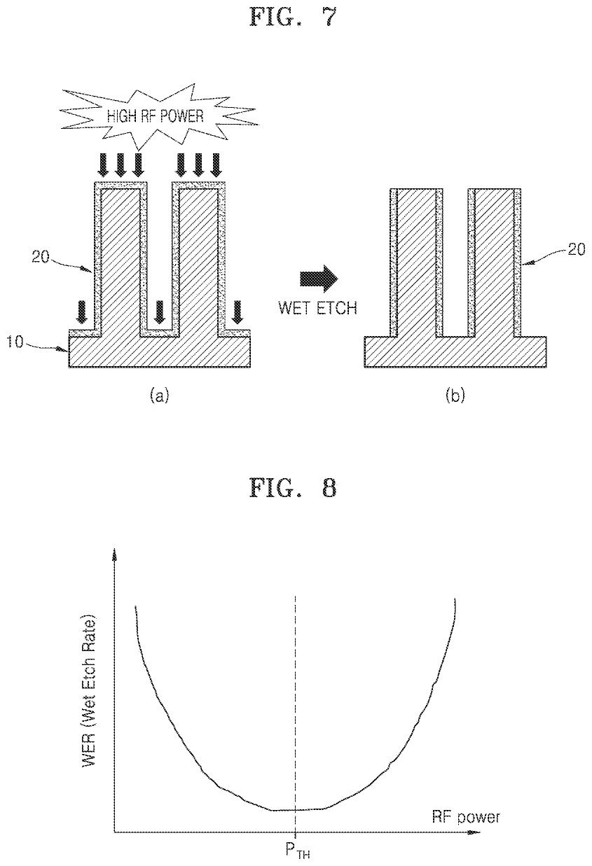

FIG. 7 is a conceptual diagram of a film formed according to a conventional substrate processing method of forming a film having high etch resistance on the side of a pattern structure, that is, a conventional substrate processing method in which films formed on top and bottom of a pattern structure are removed and a film on the side of the pattern structure remains.

A film 20 is formed using plasma on a substrate on which a pattern structure 10 is formed in FIG. 7 (a). A film is formed by plasma atomic layer deposition to form a uniform film. When high RF power is applied to form a film, due to a high ion bombardment effect of radicals, films on the top and bottom that are perpendicular to a propagation direction of radicals have lower strength and lower etch resistance than those of a film on the side parallel to the propagation direction of radicals. In general, when RF power is applied, a film becomes dense due to an ion bombardment effect, but when RF power greater than threshold RF power is applied, the film is destroyed due to excessive ion bombardment, resulting in lower strength and lower etch resistance. Therefore, when the high RF power greater than the threshold RF power is applied as shown in FIG. 7 (a), the strength of the films on the top and bottom is less than that of the film on the side. In other words, the etch resistance of the films on the top and bottom surfaces becomes less than the etch resistance of the films on the side.

Thereafter, when isotropic etching, for example, wet etching, is performed, the films on the top and bottom surfaces of the pattern structure are removed by using a difference in etch selectivities on the top and side as shown in FIG. 7(b), and the film on the side remains thereon.

FIG. 8 is a view illustrating an etch rate (WER; Wet Etch Rate) of a film according to the level of RF power applied. As described above, if RF power less than or equal to threshold RF power P_{TH} is applied when forming a film using plasma, the density of the film increases and an etch rate decreases (i.e., increase in etch resistance). However, if RF power greater than or equal to the threshold RF power is applied, the film is destroyed and the film strength is reduced, and the etch rate of the film is rather increased (i.e., reduced etch resistance).

The implementation of etch selectivity using the method shown in FIG. 7 on a pattern structure enables selective etching and selective film formation by controlling the level of applied high-frequency RF power. However, as the size of a semiconductor device decreases, a pattern structure becomes finer, and the gap between pattern structures decreases, increasing the high-frequency RF power may cause deterioration of characteristics of a film. For example, when a thinner film is deposited on a fine pattern structure having a high aspect ratio and high-frequency RF power of 800 W or more is applied to control an etch rate for a film formed on the bottom of a pattern structure, for example, the bottom of a gap, a lower film may be damaged by radicals and active ion species and may damage a reactor performing a substrate process.

The disclosure proposes a substrate processing method for avoiding the above-mentioned problems. In more detail, disclosed is a substrate processing method for controlling etch resistance of films on top, bottom, and side of a pattern structure when a low intensity of high-frequency RF power equal to or less than threshold RF power is applied.

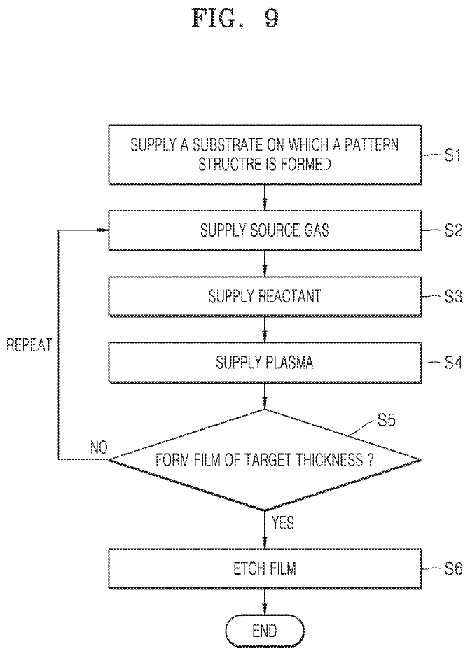

FIG. 9 is a flowchart illustrating a substrate processing method according to an embodiment. A detailed description of each step of FIG. 9 is as follows.
First step (S1): A substrate on which a pattern structure is formed is loaded into a reactor of a substrate processing device. The pattern structure may be a gate stack of a 3D NAND flash device. Alternatively, the pattern structure may be a specific pattern structure in a device element requiring selective etching of a deposition layer. The pattern structure may be composed of a photoresistor or an insulating film or a metal film.
Second step (S2): A source gas is supplied on a substrate loaded into the reactor. The source gas may be a liquid source in a source vessel and may be supplied to the substrate by a carrier gas (e.g., Ar). In an embodiment, the source gas may be a gas containing silicon. For example, the source gas may be, for example, at least one of aminosilane, iodosilane, and silicon halide gas. The supplied source gas may surface-react with the substrate to form a monolayer on the substrate.
Third step (S3): A reactant is supplied to the substrate on which molecules of the source gas are adsorbed. The reactant chemically reacts with the molecules of the source gas to form a compound on a surface of the substrate. In an embodiment, the reactant does not react with the molecules of the source gas, but a chemical reaction with the source gas may be induced by plasma supplied in a subsequent step (fourth step, S4). In an embodiment, the reactant may be a gas containing oxygen or nitrogen.
Fourth step (S4): plasma is supplied to the reactor to which the source gas and the reactant are supplied. Plasma may be formed by supplying RF power to the reactor to dissociate and ionize the reactant. By ionizing the reactant, a chemical reaction with the source gas may be promoted and a film may be formed on the substrate. In an embodiment of this step, dual-frequency RF power of low frequency and high frequency is supplied. As previously described, when supplying a high-frequency RF power of high intensity to reduce the etch resistance of films formed on the top and bottom of a pattern structure, a lower film may be damaged by active species. Therefore, by supplying a low-frequency RF power together with a low intensity of high-frequency RF power, it is possible to control the etch resistance of films formed on top, bottom, and side of a pattern structure while minimizing damage to a lower film. In an optional embodiment, the reactant may be continuously supplied throughout the third step (S3) and the fourth step (S4). Alternatively, in another embodiment, the third step (S3) and the fourth step (S4) may be performed simultaneously. Meanwhile, after the second step (S2) and after the fourth step (S4), a purge step of removing residual source gas and reactant from the reactor may be further added. In an embodiment, 300 W of 13.56 MHz high-frequency RF power or less and 300 W of 430 KHz low-frequency RF power or less may be applied together.
Fifth step (S5): It is determined whether the thickness of a film deposited on the substrate reaches a target thickness. When the thickness of the film reaches the target thickness, the deposition processes (S2 to S4) are terminated. On the other hand, when the thickness of the film does not reach the target thickness, the deposition processes (S2 to S4) are repeated again. The repeated processes may be performed by repeating a cycle previously input to a control program a plurality of times.
Sixth step (S6): An etching process is performed on the film deposited on the substrate. The etching process may be wet etching and is performed using a diluted hydrofluoric acid (dHF) solution diluted at a ratio of 1:100. This step may be performed ex-situ with the deposition processes (S2 to S5). That is, this step may be performed by transferring the substrate from the reactor in which the deposition process is performed to the reactor in which the etching processes are performed. Alternatively, a substrate on which a deposition film is formed may be unloaded from the reactor and manually transferred to a separate device capable of performing an etching process. Because the etch selectivity of a deposited film on the pattern structure is different depending on the position on the pattern structure (top, bottom, or side), films on the top and bottom are removed after this step, and a film on the side is maintained. Alternatively, the films on the top and bottom are maintained and the film on the side is removed.

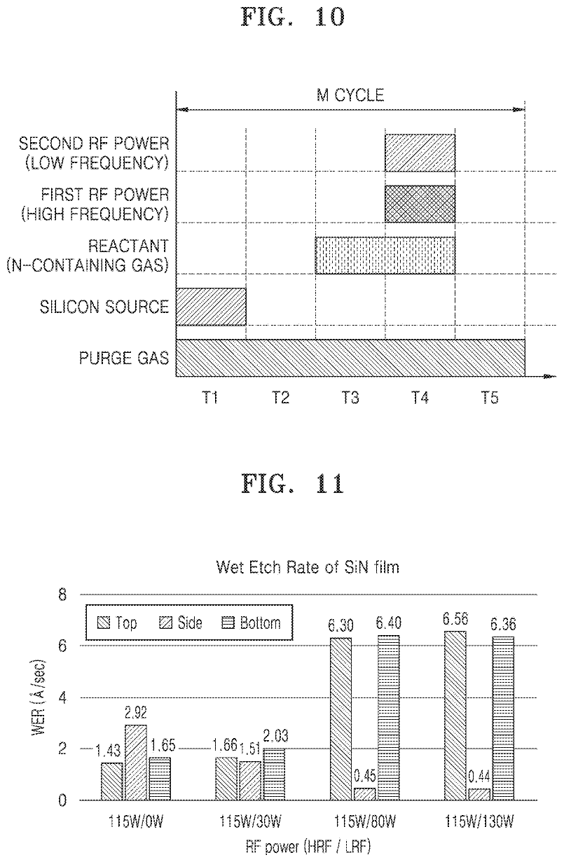

FIG. 10 shows a timing diagram for the deposition steps (S2 to S5) of FIG. 9.

Step T1 of FIG. 10 corresponds to the second step (S2) of FIG. 9, step T3 corresponds to the third step (S3) of FIG. 9, and step T4 corresponds to the fourth step (S4) of FIG. 9. As can be seen from FIG. 10, a reactant supplied in step T3 may be continuously supplied until step T4.

In step T4 of FIG. 10, first RF power and second RF power are supplied together. The first RF power is high-frequency RF power and the second RF power is low-frequency RF power. The high-frequency RF power (first RF power) increases the density of active species (ions, radicals, etc.) and the low-frequency RF power (second RF power) increases the travel distance of the active species, thereby allowing the active species to travel deeper into a gap. In other words, it is possible to achieve a technical effect of controlling the etch resistance of a film deposited on the bottom of a gap structure in addition to the top by allowing more active species to reach the bottom of a pattern structure. For example, in an embodiment, the etch resistance on the bottom as well as the top of the pattern structure having a high aspect ratio may be reduced.

In addition, the low-frequency RF power has a technical effect of reducing the etch resistance and strength of a deposited film by performing ion bombardment on the deposited film together with the high-frequency RF power.

FIG. 11 shows a wet etch rate (WER) of SiN films on top, side, and bottom after wet etching treatment is performed after depositing the SiN film on a gap structure to a certain thickness, according to the substrate processing method of FIGS. 9 and 10. Etching is performed by dipping a substrate sample in a dHF solution at room temperature (30° C.) diluted 1:100 for 10 seconds, and the WER is calculated by comparing the thickness of a film before etching and the thickness of a film after etching.

A horizontal axis of the graph of FIG. 11 represents applied RF power for forming the SiN film, and specifically, indicates that 13.56 MHz high-frequency RF power (HRF) of 115 W and 430 KHz low-frequency RF power (LRF) are applied together. As can be seen from FIG. 11, when only high-frequency RF power of 115 W is applied, that is, when low-frequency RF power is not applied, the WER of the SiN film formed on the side of the gap structure is greater than the WER of the SiN film on the top or the bottom. In other words, the SiN film on the side is removed faster than the SiN films on the top and bottom surfaces. For example, the SiN films on the top and the bottom may remain and the SiN film on the side may be removed.

On the other hand, it can be seen that when the low-frequency RF power is also applied, the WER of the SiN film on the side decreases as the intensity of the low-frequency RF power increases. As can be seen in FIG. 11, as the intensity of applied low-frequency RF power increases to 0 W, 30 W, 80 W, and 130 W, the WER of the SiN film on the side decreases to 2.92, 1.51, 0.45 and 0.44 Å/second, and the WER of the SiN films on the top and bottom surfaces increase to 1.43/1.65, 1.66/2.03, 6.30/6.40 and 6.56/6.36 Å/second, respectively. In other words, if high-intensity high-frequency RF power (e.g., 1,000 W or more) is not applied, it is difficult to lower the etch resistance of the film on the bottom, but when low-frequency RF power is applied together, a radical movement path in a gap lengthens to reach a film at the bottom of the gap structure, and lowers the etch resistance of the film at the bottom. Accordingly, there is a technical effect of compensating for the limitation in lowering the etch resistance of the film at the bottom when applying a low-intensity high-frequency RF power, by applying a low-frequency RF power and achieving wet etch uniformity of a film on the top and bottom surfaces.

FIG. 12 is a graph illustrating wet etch selectivity comparing WERs of SiN films for each location of a gap structure in FIG. 11. For example, top/side wet etch selectivity represents a wet etch rate ratio of the SiN films on the top and side of FIG. 11.

In FIG. 12, when a top/side ratio is 1.0 or less, it means that an etch rate at the side is greater than an etch rate at the top. Therefore, in such a case, the SiN film on the top remains and the SiN film on the side is removed through an etching process.

When the top/side ratio is 1.0, the etch rate on the side and the etch rate on the top surface are uniform. Therefore, in such a case, the SiN films on the top and side remain with the same thickness or are removed together through the etching process.

When the top/side ratio is greater than 1.0, the etch rate at the side is less than the etch rate at the top. Therefore, in such a case, the SiN film on the top is removed and the SiN film on the side remains through the etching process. In addition, the explanation for a bottom/side ratio is the same, so it will be omitted.

As can be seen in FIG. 12, as the level of applied low-frequency RF power (LRF) increases, the etch selectivity at the top/side and the bottom/side becomes greater than 1.0. That is, in this case, the SiN films on the top and the bottom is etched away faster than the SiN film on the side, and the SiN film on the side remains.

In addition, in FIG. 12, it can be seen that the etch selectivity of the SiN films on the top/bottom becomes 0.82, 0.98, and 1.03 as the intensity of the low-frequency RF power increases, which is close to 1.0. In other words, by applying low-frequency RF power, the etch rate on the top and bottom surfaces becomes uniform. Therefore, in a pattern structure having a high aspect ratio, there is a technical effect of removing films on the top and bottom at the same time so that there is no residual film and only a film on the side remains.

FIG. 13 is a view illustrating whether low-frequency RF power is applied and whether films on top and bottom surfaces is etched according to the intensity of applied power.

In FIG. 13 (a), when low-frequency RF power is not applied to form a film 30 on a pattern structure or applied low-frequency RF power is significantly low, after an etching process, a film remains on the bottom of the pattern structure without being completely removed. At this time, the etch selectivity of top/bottom is significantly greater than 1.0.

In FIG. 13 (b), when low-frequency RF power applied to form a film on the pattern structure is remarkably great, after an etching process, a film on the bottom of the pattern structure is removed, but a film on the top is not completely removed and remains. At this time, the etch selectivity of the top/bottom is significantly less than 1.0.

In FIG. 13 (c), when low-frequency RF power of an appropriate intensity is applied to form a film on the pattern structure, after the etching process, films on the top and bottom are removed at the same time, leaving only a film on the side. At this time, the etch selectivity of top/bottom films is close to 1.0.

Therefore, by controlling the intensity of low-frequency RF power when forming a film on the pattern structure, after the etching process, there is a technical effect of simultaneously removing the films on the top and bottom of the pattern structure without leaving any residue and leaving the film on the side.

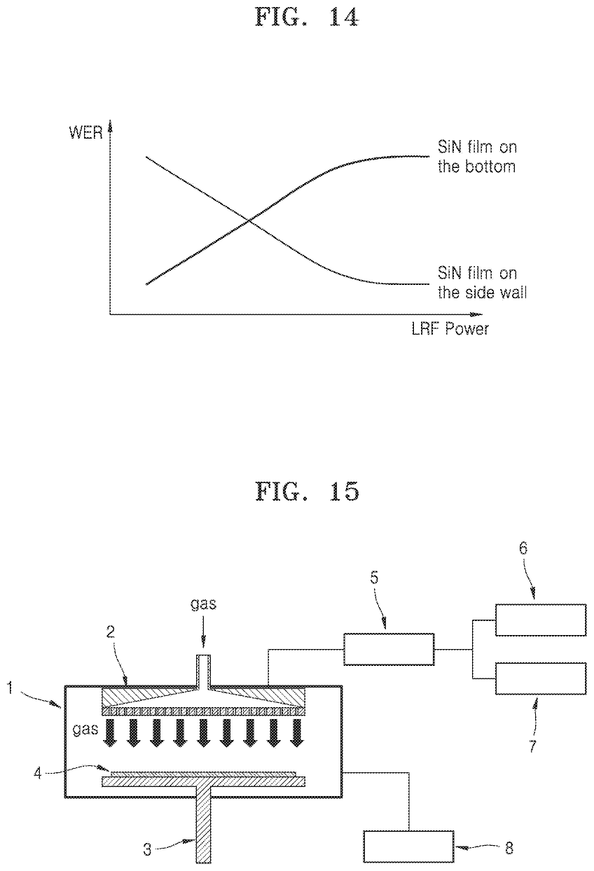

FIG. 14 is a conceptual diagram illustrating an etch rate of a film on a bottom and a side wall according to the intensity of applied low-frequency RF power. Two graphs represent an etch rate of a SiN thin-film on the side wall and an etch rate of a SiN thin-film at the bottom, respectively. It can be seen that when the intensity of the low-frequency RF power is low, an etch rate of a film at the bottom is low and an etch rate of a film on the side wall is high, but when the intensity of the low-frequency RF power is high, the etch rate of the film at the bottom is high and the etch rate of the film on the side wall is low.

Table 1 below shows a film profile of a SiN film on a pattern structure according to the intensity of the applied low-frequency RF power according to FIG. 14.

TABLE 1

| | | Intermediate | |
|---|---|---|---|
| | Low LRF power | LRF power | High LRF power |
| WER | Bottom < side wall | Bottom ≈ side | Bottom > side wall |
| | | wall | |
| Thin-film | Thin film remains on | Conformal | Thin film remains |
| profile | the bottom (and top) | | on the side wall |
| | (Topo selective film | | (Reverse topo |
| | profile) | | selective film |
| | | | profile) |

As shown in Table 1 above, when the intensity of the LRF power is low, an etch rate of a film on the side wall is high, and films on the bottom and the top remain, and when the intensity of the LRF power level is high, an etch rate of the films at the bottom and the top is high, so that the film on the side wall remains. In addition, for intermediate intensity of LRF power, the films on the side wall, bottom, and top will have the same etch rate, leaving a film of uniform thickness.

As described above, according to FIGS. 9, 10, 14 and Table 1, it can be seen that a film profile on the pattern structure may be controlled after an etching process according to the intensity of the applied low-frequency RF power without increasing the intensity of the applied high-frequency RF power.

Table 2 below shows SiN film deposition conditions according to an embodiment.

TABLE 2

| | | Experimental conditions |
|---|---|---|
| Process pressure (Torr) | | 0.5 Torr to 10.0 Torr |
| | | (preferably 2 Torr to 5 Torr) |
| Plasma | 13.56 MHz HRF power | 50 W to 300 W (preferably |
| condition | (W) | 100 W to 200 W) |
| | 430 KHz LRF power (W) | 20 W to 200 W (preferably |
| | | 30 W to 150 W) |
| Gas flow | Source (sccm) | 1,000 to 4,000 (preferably |
| condition | | 1,500 to 3,000) |
| | Source carrier Ar (sccm) | 5,000 to 10,000 (preferably |
| | | 6,000 to 9,000) |
| | Reactant | 500 to 2,000 (preferably |
| | | 1,000 to 1,500) |
| | Reactant purge Ar | 500 to 2,000 (preferably |
| | | 1,000 to 1,500) |
| | Purge Ar (sccm) | 4,000 to 10,000 (preferably |
| | | 6,000 to 8,000) |
| | Bottom fill N2 (sccm) | 2,000 to 6,000 (preferably |
| | | 3,000 to 5,000) |
| Process | Source supply (sec) | 0.1 to 1.0 (preferably 0.4 to 0.8) |
| time for | Source purge (sec) | 0.1 to 1.0 (preferably 0.4 to 0.8) |
| each step | Reactant pre-flow (sec) | 0.1 to 0.5 (preferably 0.2 to 0.4) |
| | Reactant flow and plasma | 1.0 to 4.0 (preferably 2.0 to 3.0) |
| | on (sec) | |
| | Purge (sec) | 0.1 to 0.8 (preferably 0.2 to 0.6) |

| | |
|---|---|
| Source | Dichlorosilane (DCS) |
| Reactant | NH3 |
| Number of cycles | 300 cycles |

In the evaluation conditions of Table 2, a dichlorosilane (DCS) source gas is used, but the disclosure is not limited thereto. In an embodiment, the source gas may be at least one of aminosilane, iodosilane, and silicon halide gas. For example, a silicon source may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆; TEAS, Si(NHEt)₄; Si₃H₈; DCS, SiH₂Cl₂; SiHI₃; SiH₂I₂; and dimer-trisilylamine; trimer-trisilylamine, or a derivative thereof, or a mixture thereof. A nitrogen-containing reactant may be at least one of N₂, N₂H₂ (diimide), and NH₃, or a mixture thereof.

Table 2 discloses conditions for forming a SiN film, but the disclosure is not limited thereto. For example, when an oxygen-containing reactant is supplied, a SiO₂ film may be deposited, and when forming a SiO₂ film on a pattern structure, by additionally applying low-frequency RF power in addition to high-frequency RF power, the SiO₂ film may remain on the top and bottom or a side wall after etching. Because the process control mechanism is the same as that described above, description of it will be omitted. When forming the SiO₂ film, the reactant may include at least one of O₂, O₃, CO₂, H₂O, NO₂, N₂O, or a mixture thereof.

FIG. 15 is a schematic view of a structure of a reactor for performing a film deposition according to an embodiment.

In FIG. 15, a substrate 4 is mounted on a substrate support 3 of a reactor 1, and a gas inlet 2 is arranged in the opposite direction to the substrate support 3. A space between the substrate support 3 and the gas inlet 2 may be defined as a reaction space.

The substrate support 3 may be a heating block that supplies thermal energy to the substrate 4, and the gas inlet 2 may be a showerhead. In another example, the gas inlet 2 may be configured to supply gas laterally. Gas is supplied from the outside to the substrate 4 in the reactor 1 through the gas inlet 2, and a processed gas is exhausted through an exhaust unit 8. The exhaust unit 58 may be an exhaust pump.

A substrate processing device may include a power generator. The power generator may be configured to apply plasma to a reactor providing a reaction space. As a specific example, the gas inlet 2 may be electrically connected to the power generator, and the gas inlet 2 functions as an electrode so that plasma may be generated in the reactor and applied to the reaction space. In another example, plasma may be generated outside the reactor and applied into the reactor.

In some examples, the power generator may include a matching network 5, a high-frequency RF power generator 6, and a low-frequency RF power generator 7. The matching network 5 between the power generator and the reactor may function to prevent power generated by the power generator from being reflected. In other words, the matching network 5 may be configured to perform impedance matching between the high-frequency RF power generator 6 and the low-frequency RF power generator 7 and the reactor.

In a further example, the high-frequency RF power generator 6 may be configured to generate first plasma of a high frequency (e.g., 13.56 MHz). The low-frequency RF power generator 7 may be configured to generate second plasma of a low frequency (e.g., 430 kHz).

In an embodiment, when performing film deposition, a source gas and a reactant are alternately supplied sequentially, and when the reactant is supplied, the high-frequency RF power generator 6 and the low-frequency RF power generator 7 supply high-frequency RF power and low-frequency RF power to the reactor 1, respectively.

In an embodiment, a film having a selective etch ratio may be formed on a pattern structure having a fine pattern structure. In more detail, in order to minimize damage to a lower film, a film having a selective etch rate may be formed on a pattern structure by applying low-frequency RF power in addition to low-intensity high-frequency RF power. In an embodiment, by controlling the level of low-frequency RF power, the etch rate of a film on the top, bottom, or side of the pattern structure may be controlled, and the film may be selectively left on the top, bottom or side.

In addition, it is possible to achieve wet etch rate uniformity of the films on the top and bottom, so that there is no remaining film on the top and bottom after an etching process, and only the film on the side may remain.

It is to be understood that the shape of each portion of the accompanying drawings is illustrative for a clear understanding of the disclosure. It may be noted that the portions may be modified into various shapes other than the shapes shown. In the drawings, the same reference numerals refer to the same elements.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

1. A substrate processing method comprising:
supplying a substrate having a pattern structure;
forming a layer on the pattern structure;
generating active species by applying plasma; and
selectively etching the layer on the pattern structure generated by the active species by performing isotropic etching on the layer,
wherein the applying of the plasma comprises:
increasing a density of the active species; and
increasing a mobility of the active species.

2. The substrate processing method of claim 1, wherein the forming a layer on the pattern structure comprising:
supplying a first gas; and
supplying a second gas,
wherein a cycle including the supplying of the first gas, the supplying of the second gas, and generating active species by applying the plasma is performed a plurality of times, and
the isotropic etching is performed after the cycle.

3. The substrate processing method of claim 1, wherein
the increasing of the density of active species is performed by applying first plasma, and
the increasing of the mobility of active species is performed by applying second plasma different from the first plasma.

4. The substrate processing method of claim 3, wherein
a frequency of the first plasma is greater than a frequency of the second plasma.

5. The substrate processing method of claim 3, wherein
a location of a portion where the layer is etched by the isotropic etching depends on a first ratio of a second power intensity of the second plasma to a first power intensity of the first plasma.

6. The substrate processing method of claim 5, wherein
the first power intensity is in a range of about 50 W to about 300 W.

7. The substrate processing method of claim 6, wherein
the first power intensity is in a range of about 100 W to about 200 W.

8. The substrate processing method of claim 5, wherein
the second power intensity is in a range of 30 W to 150 W.

9. The substrate processing method of claim 5, wherein
the first ratio exceeds a certain value, and the layer remains on a side of the pattern structure.

10. The substrate processing method of claim 9, wherein
the pattern structure comprises a top, a bottom, and the side connecting the top and the bottom, and
the layer comprises a first layer on the top, a second layer on the bottom, and a third layer on the side,
wherein during the isotropic etching, the first layer is etched at a first etch rate, the second layer is etched at a second etch rate, and the third layer is etched at a third etch rate.

11. The substrate processing method of claim 10, wherein
the third etch rate is less than the first etch rate and less than the second etch rate.

12. The substrate processing method of claim 10, wherein
a second ratio of the first etch rate to the second etch rate is proportional to an increase in the first ratio.

13. The substrate processing method of claim 1, wherein
the substrate processing method is performed using a substrate processing device, and
the substrate processing device comprises a power generator configured to apply plasma.

14. The substrate processing method of claim 13, wherein
the substrate processing device further comprises a matching network between the power generator and a reactor.

15. The substrate processing method of claim 14, wherein
the power generator comprises:
a first power generator configured to generate a first plasma having a first frequency; and
a second power generator configured to generate a second plasma having a second frequency less than the first frequency.

16. The substrate processing method of claim 15, wherein
the matching network is configured to perform an impedance matching between the first and second power generators and the reactor.

17. A substrate processing method comprising:
supplying a substrate having a pattern structure;
forming a layer on the pattern structure by applying a first plasma having a first frequency and a second plasma having a second frequency less than the first frequency; and
performing a selective etching on the layer by isotropically etching the layer,
wherein a location of a portion where the layer remains by the selective etching depends on a ratio of a second power intensity of the second plasma to a first power intensity of the first plasma.

18. The substrate processing method of claim 17, wherein
a cycle is repeated several times during the forming of the layer,
the cycle comprising:
supplying a first gas;
purging the first gas;
supplying a second gas;
applying the first plasma;
applying the second plasma; and
purging the second gas.

19. A substrate processing device comprising:
a substrate support configured to support a substrate;
a gas inlet on the substrate support;
a first power generator connected to the gas inlet; and
a second power generator connected to the gas inlet,
wherein a first frequency of first plasma generated by the first power generator is greater than a second frequency of second plasma generated by the second power generator.

20. The substrate processing device of claim 19, further comprising:
a matching network between the gas inlet and the first and second power generators.
